(19) United States
(12) Patent Application Publication
(10) Pub. No.: US 2026/0209944 A1
(43) Pub. Date: Jul. 23, 2026

(54) MULTI-PORT GAS INJECTION SYSTEM AND REACTOR SYSTEM INCLUDING SAME

(71) Applicant: ASM IP Holding B.V., Almere (NL)

(72) Inventors: Mingyang Ma, Phoenix, AZ (US); Junwei Su, Tempe, AZ (US); Alexandros Demos, Scottsdale, AZ (US); Xing Lin, Chandler, AZ (US); Sam Kim, Chandler, AZ (US); Gregory Michael Bartlett, Phoenix, AZ (US)

(21) Appl. No.: 19/571,724

(22) Filed: Mar. 19, 2026

Related U.S. Application Data
(63) Continuation of application No. 17/352,011, filed on Jun. 18, 2021, now Pat. No. 12,601,062.
Application No. 17/352,011 is a continuation of application No. 16/055,532, filed on Aug. 6, 2018, now Pat. No. 11,053,591.

(51) Int. Cl. C23C 16/52; B01J 4/00; C23C 16/44; C23C 16/455; H01J 37/32

(52) U.S. Cl. CPC C23C 16/52; B01J 4/008; C23C 16/4401; C23C 16/45502; C23C 16/45523; C23C 16/45561; C23C 16/45574; C23C 16/45587; H01J 37/3244

(57) ABSTRACT

A gas injection system, a reactor system including the gas injection system, and methods of using the gas injection system and reactor system are disclosed. The gas injection system can be used in gas-phase reactor systems to independently monitor and control gas flow rates in a plurality of channels of a gas injection system coupled to a reaction chamber.

### CROSS-REFERENCE TO RELATED APPLICATIONS

This application is a Continuation of, and claims priority to and the benefit of, U.S. patent application Ser. No. 17/352,011 filed Jun. 18, 2021 titled “MULTI-PORT GAS INJECTION SYSTEM AND REACTOR SYSTEM INCLUDING SAME”; which is a continuation of U.S. patent application Ser. No. 16/055,532, filed Aug. 6, 2018 titled “MULTI-PORT GAS INJECTION SYSTEM AND REACTOR SYSTEM INCLUDING SAME” (now U.S. Pat. No. 11,053,591 issued on Jul. 6, 2021) which is hereby incorporated by reference herein.

### FIELD OF THE DISCLOSURE

The present disclosure generally relates to gas-phase reactors and systems. More particularly, the disclosure relates to gas injection systems for introducing gas to a reaction chamber, to reactors and reactor systems including a gas injection system, and to methods of using same.

### BACKGROUND OF THE DISCLOSURE

Gas-phase reactors, such as chemical vapor deposition (CVD), plasma-enhanced CVD (PECVD), and atomic layer deposition (ALD) reactors, can be used for a variety of applications, including depositing and etching materials on a substrate surface. For example, gas-phase reactors can be used to deposit and/or etch layers on a substrate to form semiconductor devices, flat panel display devices, photovoltaic devices, microelectromechanical systems (MEMS), and the like.

A typical gas-phase reactor system includes a reactor including a reaction chamber, one or more precursor and/or reactant gas sources fluidly coupled to the reaction chamber, one or more carrier and/or purge gas sources fluidly coupled to the reaction chamber, a gas injection system to deliver gases (e.g., precursor/reactant gas(es) and/or carrier/purge gas(es)) to the reaction chamber, and an exhaust source fluidly coupled to the reaction chamber.

Generally, it is desirable to have uniform film properties (e.g., film thickness and resistivity) across a surface of a substrate and/or to have control over any desired variation. Various gas injection systems have been developed to attempt to achieve uniform or controllable film properties. For example, gas injection systems including multiple ports or nozzles located within or adjacent the reaction chamber have been developed to increase uniformity of film properties across a substrate surface. In such examples, a flow rate of gas to each port can be adjusted—e.g., manually, using a needle valve. Although this technique works well for some applications, such systems may not be able to accurately monitor and control gas flow to adequately address desired uniformity and/or controllability of film properties, particularly at or near an edge of a substrate. Additionally, use of the needle valve may generate undesired particles—e.g., due to mechanical abrasion of valve components.

As sizes of features formed on a substrate surface decrease, it becomes increasingly important to control film properties, such as film thickness and resistivity. Moreover, it may be desirable to independently tune film properties; e.g., to independently tune film thickness uniformity and/or resistivity in layers deposited using gas-phase reactors, such as epitaxial layers grown using such reactors. Accordingly, improved gas injection systems, reactor systems including an improved gas injection system, and methods of using the gas injection and reactor systems are desired.

### SUMMARY OF THE DISCLOSURE

Various embodiments of the present disclosure relate to gas injection systems, reactors and reactor systems including a gas injection system, and to methods of using the gas injection systems, reactors, and reactor systems. While the ways in which various embodiments of the present disclosure address drawbacks of prior gas injection systems, reactors, and systems are discussed in more detail below, in general, various embodiments of the disclosure provide gas injection systems that can provide improved monitoring and control of gas (e.g., a mixture of gases) flow rates to individual channels of a gas injection system, provide dynamic feedback of flow and/or flow ratios of gas to one or more channels of a gas injection system, and/or provide improved stability of flow rates and/or flow ratios of gas in each channel of a gas injection system. Further, exemplary systems and methods allow fine tuning of precursors and reactants provided to a reaction chamber and/or a substrate surface. In addition, exemplary gas injection systems can allow for independent tuning of film properties, such as film thickness, film thickness uniformity, film resistivity, composition profiles, and the like. Exemplary gas injection systems can also be used to maintain pressure differentials at desired levels.

In accordance with exemplary embodiments of the disclosure, a gas injection system includes a first gas supply line; a first gas manifold coupled to the first gas supply line, wherein the first gas manifold comprises a plurality of first gas outlets; a plurality of first mass flow sensors, wherein at least one of the plurality of first gas flow sensors is coupled to each of the plurality of first gas outlets; a plurality of first gas valves, wherein at least one of the plurality of first gas valves is coupled to an outlet of each of the plurality of first gas flow sensors; and a controller (electrically) coupled to the plurality of first mass flow sensors and to the plurality of first gas valves to control a desired flow ratio of a first gas through each of a plurality of first gas channels. Exemplary gas injection systems can also include a second gas supply line; a second gas manifold coupled to the second gas supply line, wherein the second gas manifold comprises a plurality of second gas outlets; a plurality of second gas flow sensors, wherein at least one of the plurality of second gas flow sensors is coupled to each of the plurality of second gas outlets; a plurality of second gas valves, wherein at least one of the plurality of second gas valves is coupled to an outlet of each of the plurality of second gas flow sensors; and wherein a controller (e.g., the same controller coupled to the plurality of first mass flow sensors and to the plurality of first gas valves) is coupled to the plurality of second mass flow sensors and to the plurality of second gas valves to control a desired flow ratio of a second gas through each of a plurality of second gas channels. Gas injection systems in accordance with the present disclosure can similarly include three of more gas lines and the corresponding components, as described in connection with the first and second gas lines and can use one or more controllers as described herein. Use of the flow controllers as described herein can allow independent control of gas flow rates to one or more channels (described in more detail below) of a gas injection system, which, in turn, can allow for fine tuning of various properties of films deposited using such systems and/or reactant/precursor concentration profiles within a reaction chamber.

In accordance with additional exemplary embodiments of the disclosure, a gas-phase reactor system includes one or more gas injection systems as described herein. The exemplary systems can also include an exhaust (e.g., vacuum) source coupled to the reaction chamber, a first gas source fluidly coupled to the one or more first gas channels, and a second gas source fluidly coupled to the one or more second gas channels. Exemplary systems can also include additional gas (e.g., dopant sources) and/or exhaust sources.

In accordance with yet additional exemplary embodiments of the disclosure, a method of providing gas-phase reactants to a surface of a substrate includes the steps of providing a gas-phase reactor system, providing a gas injection system as described herein, providing a substrate within a reaction chamber of the reactor system, and exposing the substrate to a first gas from the first gas source and a second gas from the second gas source. Exemplary methods can further include automatically adjusting one or more valves coupled to the one or more first gas channels and/or automatically adjusting one or more valves coupled to the one or more second gas channels. Exemplary methods can also include a step of providing an asymmetric setting of one or more of a first gas from the first gas source and a second gas from the second gas source—to, e.g., tune (e.g., independently) film properties, such as film thickness, film thickness uniformity, and film resistivity across a surface of a substrate, including an edge region of the substrate, and the like.

### BRIEF DESCRIPTION OF THE DRAWING FIGURES

A more complete understanding of exemplary embodiments of the present disclosure can be derived by referring to the detailed description and claims when considered in connection with the following illustrative figures.

FIG. 1 illustrates a reactor system in accordance with at least one exemplary embodiment of the present disclosure.

FIG. 2 schematically illustrates a gas injection system in accordance with at least one exemplary embodiment of the disclosure.

FIG. 3 schematically illustrates another view of the gas injection system in accordance with at least one exemplary embodiment of the disclosure.

FIG. 4 schematically illustrates a portion of a control system in accordance with at least one exemplary embodiment of the disclosure.

FIG. 5 schematically illustrates a control system in accordance with at least one exemplary embodiment of the disclosure.

It will be appreciated that elements in the figures are illustrated for simplicity and clarity and have not necessarily been drawn to scale. For example, the dimensions of some of the elements in the figures may be exaggerated relative to other elements to help to improve the understanding of illustrated embodiments of the present disclosure.

### DETAILED DESCRIPTION OF EXEMPLARY EMBODIMENTS OF THE DISCLOSURE

The description of exemplary embodiments provided below is merely exemplary and is intended for purposes of illustration only; the following description is not intended to limit the scope of the disclosure or the claims. Moreover, recitation of multiple embodiments having stated features is not intended to exclude other embodiments having additional features or other embodiments incorporating different combinations of the stated features.

The present disclosure generally relates to gas injection systems, to reactors and reactor systems including a gas injection system, and to methods of using the gas injection systems and systems. Gas injection systems, reactors, and reactor systems including a gas injection system as described herein, can be used to process substrates, such as semiconductor wafers. By way of examples, the systems described herein can be used to form or grow epitaxial layers (e.g., two component and/or doped semiconductor layers) on a surface of a substrate. Exemplary systems can be further used to provide etch chemistry to a substrate surface. For example, exemplary systems can provide a mixture of two or more gases (e.g., collectively referred to herein as a mixture or simply gas or first gas) during a deposition (e.g., growth) process and/or two or more gases (e.g., collectively referred to herein as a mixture or simply gas or second gas) during an etch process. Both the deposition and etch gases can be used to grow an epitaxial film on a substrate.

As used herein, the terms “precursor” and/or “reactant” can refer to one or more gases/vapors that take part in a chemical reaction or from which a gas-phase substance that takes part in a reaction is derived. The chemical reaction can take place in the gas phase and/or between a gas phase and a surface of a substrate and/or a species on a surface of a substrate.

As used herein, a “substrate” refers to any material having a surface onto which material can be deposited. A substrate may include a bulk material such as silicon (e.g., single crystal silicon) or may include one or more layers overlying the bulk material. Further, the substrate may include various topologies, such as trenches, vias, lines, and the like formed within or on at least a portion of a layer of the substrate.

As set forth in more detail below, use of exemplary gas injection systems as described herein is advantageous, because it allows independent metering and control of gas (e.g., a gas mixture) flow through various channels of the gas injection systems, and, in turn, to input sites of a reaction chamber. The independent control of gas flow can, in turn, allow independent tuning of film properties of films that are formed using a reactor system including the gas injection system. For example, an exemplary gas injection system can be used to independently tune resistivity and film thickness (or thickness uniformity) of, for example, epitaxially formed layers on a substrate. Additionally or alternatively, exemplary gas injection systems can be used to compensate for gas flow variations, depletion rate variations, auto doping, or combinations thereof that may otherwise occur within a reaction chamber of a reactor system. For example, the independent gas flow control at various input sites can be used to compensate for edge effects and/or a rotating substrate, which might otherwise cause undesired nonuniformity in one or more film properties. Further, exemplary gas injection systems can provide real-time feedback of gas flow in each channel. Exemplary gas injection systems are scalable to any desired number of channels and can be used with gas mixtures, while maintaining desired precision and control of flow rates (e.g., independent of the makeup of the gas mixture). Additionally, exemplary gas injection systems of the present disclosure can be used for relatively high gas flow rates (e.g., greater than five standard liters per minute of nitrogen through each channel) and/or can operate at relatively high (e.g., near atmospheric) pressures, if desired. These and other features of the systems and methods described herein can be particularly useful in depositing high-quality epitaxial layers on substrates.

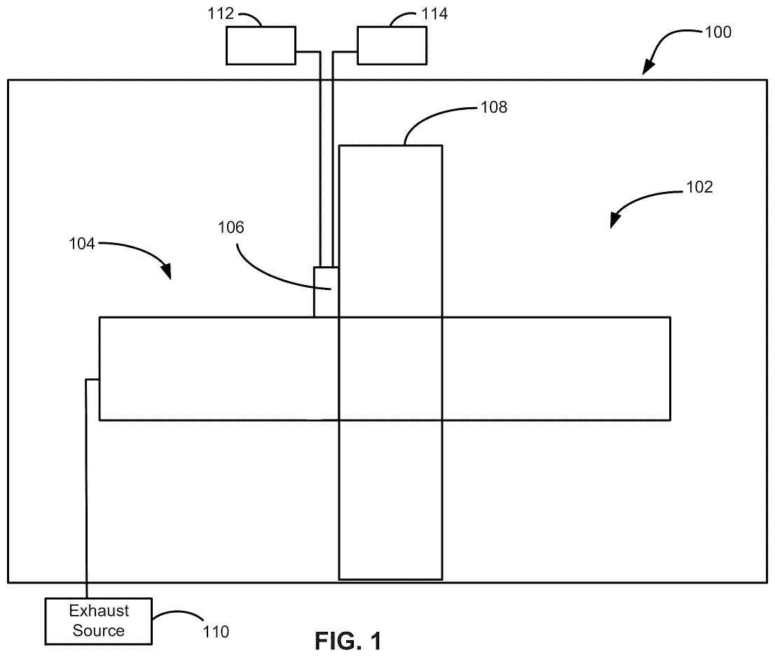

Turning now to the figures, FIG. 1 illustrates an exemplary reactor system 100. Reactor system 100 can be used for a variety of applications, such as, for example, chemical vapor deposition (CVD), plasma-enhanced CVD (PECVD), atomic layer deposition (ALD), clean processes, etch processes, and the like. Although exemplary embodiments are described below in connection with epitaxial reactor systems, the embodiments and the invention are not so limited, unless stated otherwise.

In the illustrated example, reactor system 100 includes an optional substrate handling system 102, a reaction chamber 104, a gas injection system 106, and optionally a wall 108 disposed between reaction chamber 104 and substrate handling system 102. System 100 can also include a first gas source 112, a second gas source 114, and an exhaust source 110. Although illustrated with two gas sources 112, 114, reactor system 100 can include any suitable number of gas sources. Gas sources 112, 114 can include, for example, a precursor gas, such as trichlorosilane, dichlorosilane, silane, disilane, and trisilane; a dopant source, such as a gas comprising As, P, C, Ge, and B; and mixtures of gases, including mixtures of gases with a carrier gas, such as hydrogen, nitrogen, argon, helium or the like. Additionally or alternatively, one of first gas source 112 and second gas source 114 can include an etchant, such as a chlorine-containing gas, such as hydrogen chloride. By way of examples, first gas source 112 and/or second gas source 114 comprise a mixture of gases. Reactor system 100 can include any suitable number of reaction chambers 104 and substrate handling systems 102. By way of example, reaction chamber 104 of reactor system 100 includes a cross flow, cold wall epitaxial reaction chamber. An exemplary reactor system including a horizontal cross flow reactor is available as a system from ASM (e.g., the ASM Intrepid® reactor system).

During operation of reactor system 100, substrates, such as semiconductor wafers, (not illustrated) are transferred from, e.g., substrate handling system 102, to reaction chamber 104. Once substrate(s) are transferred to reaction chamber 104, one or more gases from gas sources 112, 114, such as precursors, dopants, carrier gases, and/or purge gases are introduced into reaction chamber 104 via gas injection system 106. As set forth in more detail below, gas injection system 106 can be used to meter and control gas flow of one or more gases from first gas source 112 and second gas source 114 during substrate processing and to provide desired flows of such gas(es) to multiple sites within reaction chamber 104.

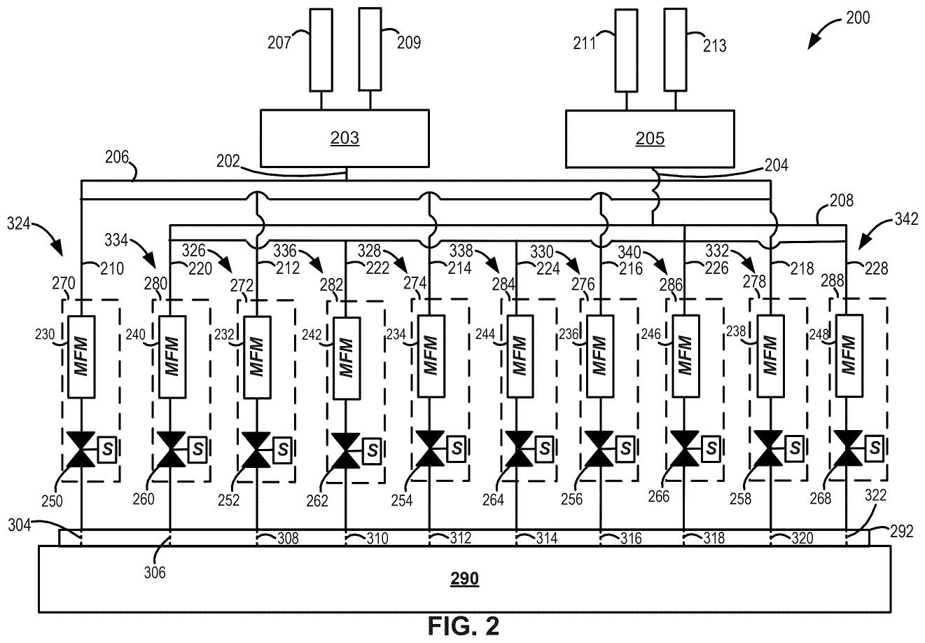

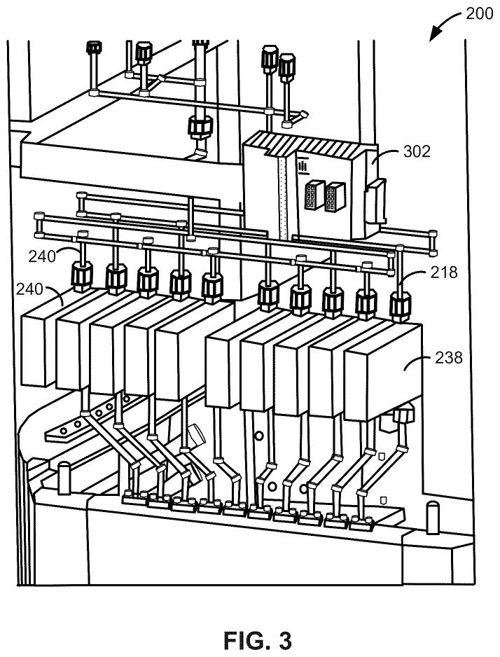

FIGS. 2 and 3 schematically illustrate a gas injection system 200, suitable for use as gas injection system 106, in accordance with exemplary embodiments of the disclosure. Gas injection system 200 includes a first gas supply line 202 coupled to a first gas source 203, which can be the same or similar to gas source 112, and a second gas supply line 204 coupled to a second gas source 205, which can be the same or similar to gas source 114. When referring to gas lines and fluid components of gas injection system 200, the term “coupled” refers to fluidly coupled, and, unless stated otherwise, the lines or components need not be directly fluidly coupled, but rather gas injection system 200 could include other intervening elements, such as connectors, valves, meters, or the like.

With continued reference to FIGS. 2 and 3, gas injection system 200 includes a first gas manifold 206 coupled to first gas supply line 202 and a second gas manifold 208 coupled to second gas supply line 204. First gas manifold 206 includes a plurality of first gas outlets 210-218. Similarly, second gas manifold 208 includes a plurality of second gas outlets 220-228. First gas manifold 206 and second gas manifold 208 are configured to receive gas from one or more gas lines (e.g., first and second gas lines 202, 204) and distribute the gas into one or more first channels 324-332 and one or more second channels 334-342, which are respectively defined, in part, by first gas outlets 210-218 and second gas outlets 220-228. In the illustrated example, each of the first and second gas streams from first gas source 203 and second gas source 205 is divided into five gas channels first channels 324-332 and five second channels 334-342. Although illustrated with five of each of first gas outlets 208-218 and second gas outlets 220-228, gas injection systems in accordance with this disclosure can include any suitable number of first, second, and/or other gas outlets, corresponding to a number of channels for the respective gases. For example, exemplary systems can include, for example, about 1-10 channels or include 5, 6, 7, 9, or more channels for each gas. As illustrated, first gas manifold 206 and/or second gas manifold 208 can include a loop configuration to facilitate even flow distribution through the gas channels. In the illustrated examples, first gas channels and second gas channels are alternatingly adjacent each other. However, this need not be the case.

As noted above, first gas source 203 and/or second gas source 205 can be a mixture of two or more gases. In such cases, one or more gases, which may, in turn, include a mixture of gases- or not, can be supplied from other sources (not illustrated) to first gas source 203 and/or second gas source 205 via flow controllers 207-213. When the source gases upstream of flow controllers 207-213 are not mixtures of gases, flow controllers 207-209 can suitably be mass flow controllers.

Gas injection system 200 additionally includes a plurality of flow sensors 230-248 coupled to first and second gas outlets 210-228. In the illustrated example, each first and second gas outlets 210-228 is coupled to a single flow sensor 230-248. However, in some cases, it may be desirable to have some gas outlets that are not coupled to a flow sensor and/or to have some gas outlets that are coupled to more than one flow sensor.

Flow sensors 230-248 can be used to monitor flow rates of gas mixtures and to provide real-time and/or historical flow rate information to a user for each channel—e.g., using a graphical user interface. Additionally or alternatively, flow sensors 230-248 can be coupled to a controller (e.g., controller 302) and to gas valves 250-258 to provide controlled flow ratio of the gases through gas valves 250-268. By placing at least one flow sensor 230-248 in each gas channel, the flow ratio (e.g., relative flow rate) of gas through each channel can be measured and controlled, regardless of the gas composition. Exemplary flow sensors 230-248 can be or include various flow sensors, e.g., thermal mass flow sensors, pressure drop based flow sensors.

Gas valves 250-268 can include any suitable device to meter flow of a gas. In accordance with various embodiments of the disclosure, gas valves 250-258 each comprise proportional valves, such as solenoid valves, pneumatic valves, or piezoelectric valves. A valve with a relatively high (e.g., 0.021-0.14) flow coefficient (Cv) may be selected to reduce chocking downstream. As discussed in more detail below, gas valves 250-268 may desirably operate under closed-loop control, but may also be capable (e.g., additionally) of operating under open-loop control.

Flow sensors 230-248 and gas valves 250-268 can initially form part of, for example, a mass flow controller (e.g., an off-the-shelf mass flow controller), wherein the control function of the valve is replaced by controller 302. For example, flow meter 230 and gas valve 250 can form or be part of a mass flow controller 270 that is set to operate in open-loop mode and wherein controller 302 provides closed-loop control of valves 250-268. Flow sensors 232-248 and gas valves 252-258 can similarly form or be part of a mass flow controller 272-288. This configuration allows for implementation in standard reactor configurations and/or for use of readily-available mass flow controllers and flow sensors and valves.

Gas valves 250-268 can be coupled to a reaction chamber 290 via a flange 292. Additional line (e.g., tubing) and suitable connectors can be used to couple gas valves 250-268 to flange 292. Exemplary flange 292 includes flange gas channels 304-322 to maintain the channels until the respective gases exit into reaction chamber 290. An exemplary flange suitable for use as flange 290 is disclosed in U.S. application Ser. No. 14/218,690, filed Mar. 18, 2014, and entitled GAS INJECTION SYSTEM, REACTOR INCLUDING THE SYSTEM, AND METHODS OF USING THE SAME, the contents of which are hereby incorporated herein by reference, to the extent such contents do not conflict with the present disclosure.

Gas injection system 200 can optionally include a moisture sample panel. A moisture sample panel can include, for example, one or more pressure transducers, pneumatic valves, and/or restrictors. An exemplary moisture sample panel is disclosed in U.S. application Ser. No. 15/997,445, filed Jun. 4, 2018, and entitled GAS DISTRIBUTION SYSTEM AND REACTOR SYSTEM INCLUDING SAME, the relevant contents of which are hereby incorporated herein by reference, to the extent such contents do not conflict with the present disclosure.

Reaction chamber 290 can be formed of, for example, quartz. Exemplary operating pressures within reaction chamber 290 during substrate processing can range from, for example, about 0.5 mTorr to about 780 Torr. By way of examples, the pressure can range from about 2 mTorr to about 780 Torr. In accordance with exemplary embodiments of the disclosure, system 200 can provide desired, stable, independent flow control within each channel over such pressure ranges.

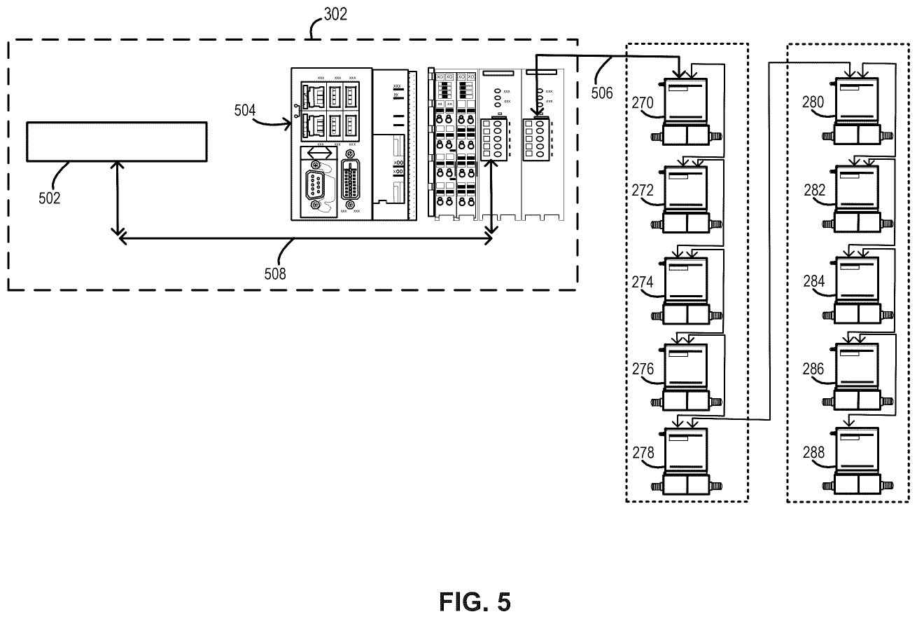

Controller 302 can be configured to perform various functions and/or steps as described herein. Controller 302 can include one or more microprocessors, memory elements, and/or switching elements to perform the various functions. Although illustrated as a single unit, controller 302 can alternatively comprise multiple devices, as illustrated in FIG. 5. By way of examples, controller 302 can be used to control flow of gas from first gas source 203 and/or second gas source 205 in a plurality of gas channels. Controller 302 can be configured to provide open-loop and/or closed-loop flow control using, for example, the same hardware. In particular, controller 302 can be configured to provide desired ratios of a total flow of a respective gas (e.g., from first gas source 203 or second gas source 205) in each of the channels coupled to the respective sources. In accordance with various examples of the disclosure, controller 302 includes proportional-integral-derivative (PID) controllers, which allow independent, closed-loop control of the various controllable valves described herein, including gas valves 250-268. With PID closed-loop control, system 200 can dynamically adjust flows in one or more (e.g., all) gas channels to set points and/or provide stable, especially initial, flow rates of gases to reaction chamber 290 when switching between gas sources and/or when the operating pressure is relatively high (e.g., near atmospheric pressure). The closed-loop control allows for automatic and stable control of flow rates through each channel over a wide variety of pressure ranges, such as those set forth herein. The closed-loop control further allows for control without tool matching, which is often required for traditional systems. By way of example, using PID control, an initial set point for each controlled valve can be selected. Flow ratio feedback from an output of each flow sensor coupled to the controllable valve can then be used in connection with a PID controller of controller 302 to control the desired set point (i.e., flow ratio) of each of the controlled valves.

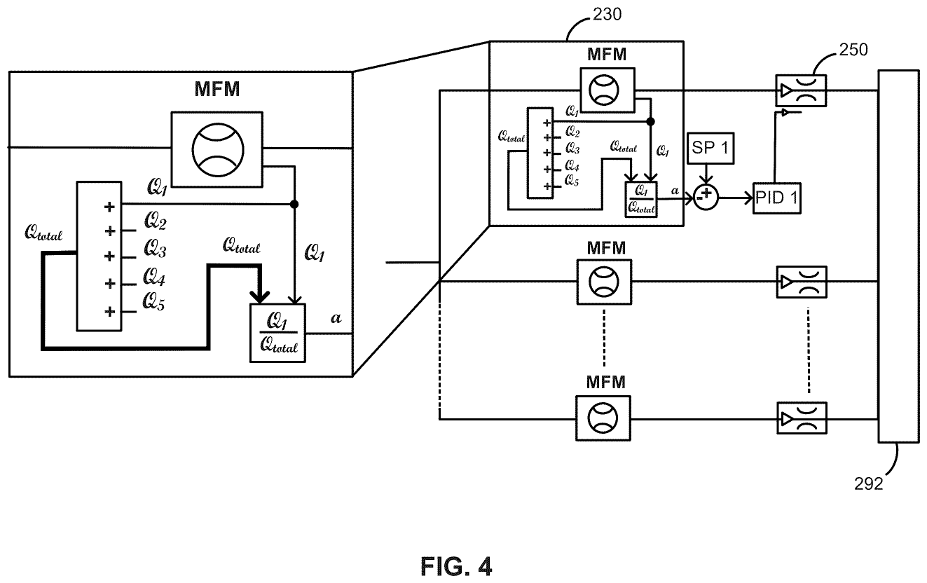

FIG. 4 illustrates a portion of controller 302 for controlling a flow through a channel of gas injection system 200 using a typical mass flow controller, while overriding the control function of the mass flow controller. Initially, based on a flow ratio set point (e.g., from a process recipe) for each channel, controller 302 will first determine the channel with highest flow ratio, and set its correlated control valve to a set point, typically below 100% open, such as 90% constant open. Next, real-time nitrogen equivalent flow rate through each channel is measured using the respective flow meters. In the illustrated example, the flow is measured by 5 flow meters as: Q1, Q2, Q3, Q4, Q5. Then the total flow rate is calculated by summing up the flow rate through each channel as:

$${Q}_{total} = {\sum }_{i = 5}^{5} {Q}_{i} .$$

Actual flow ratios through each channel are then calculated as:

$$α = \frac{{Q}_{1}}{{Q}_{total}} , β = \frac{{Q}_{2}}{{Q}_{total}} , γ = \frac{{Q}_{3}}{{Q}_{total}} δ = \frac{{Q}_{4}}{{Q}_{total}} , θ = \frac{{Q}_{5}}{{Q}_{total}} ;$$

the actual ratios, as measure, can be displayed on a graphical user interface. In addition to the channel with the highest flow ratio, the rest of real time flow ratios are compared with their respective initial set points. An error function (ε) is then calculated for each valve as the difference between a flow ratio feedback and a flow ratio set point. The error function for each channel is used as PID input in controller 302 for each channel/valve to be controlled. The PID output will be the command signal to control the respective valve in each channel.

FIG. 5 illustrates controller 302 in greater detail. In the illustrated example, controller 302 includes a main controller 502 and a programmable logic controller (PLC) 504. Main controller 502 can be used to send flow ratio set points to PLC 504 and to receive feedback from PLC 504. In this configuration, main controller 502 acts as a master controller and PLC controller 504 acts as a slave to main controller 502. PLC controller 504 performs (e.g., using embedded firmware) the PID and control functions described above in connection with FIG. 4. PLC 504 can also be used to control valves 250-268 in an open-loop configuration—e.g., to allow fast-response, stable open-loop control. The communication between sensors 230-248, valves 250-268 (e.g., via controllers 270-288), PLC 504, and main controller 502 can be digital and can be transmitted using suitable cables 506, 508.

Although exemplary embodiments of the present disclosure are set forth herein, it should be appreciated that the disclosure is not so limited. For example, although the gas injection and reactor systems are described in connection with various specific configurations, the disclosure is not necessarily limited to these examples. Various modifications, variations, and enhancements of the system and method set forth herein may be made without departing from the spirit and scope of the present disclosure.

The subject matter of the present disclosure includes all novel and nonobvious combinations and subcombinations of the various systems, components, and configurations, and other features, functions, acts, and/or properties disclosed herein, as well as any and all equivalents thereof.

We claim:

1. A gas injection system, comprising:
a gas supply line;
a gas manifold coupled to the gas supply line having a plurality of gas outlets;
a plurality of mass flow sensors, wherein each of the plurality of mass flow sensors is coupled to a respective gas outlet;
a plurality of gas valves, wherein each of the plurality of gas valves is coupled to an outlet of a respective mass flow sensor; and
a controller electrically coupled to each of the plurality of mass flow sensors and each of the plurality of gas valves, the controller responsive to instructions recorded on a non-transitory machine-readable memory and configured to control a flow rate through each of the plurality of valves using closed-loop flow control, wherein controlling the flow rate through each of the plurality of valves comprises the controller:
transmitting a respective setpoint for each of the plurality of gas valves, wherein each of the plurality of gas valves is configured to flow gas at an initial flow rate based on the respective setpoint,
receiving a respective flow rate measurement for each of the plurality of gas valves,
determining a respective measured flow ratio for each of the plurality of gas valves, wherein the respective measured flow ratio is the respective flow rate measurement divided by the sum of each flow rate measurement for each of the plurality of gas valves,
determining a respective difference between the respective flow rate measurement and a respective setpoint for each of the plurality of gas valves, and
controlling the flow rate for each of the plurality of gas valves based on the respective difference.

2. The gas injection system of claim 1, wherein each of the plurality of mass flow sensors is coupled to the respective gas outlet only of the plurality of gas outlets.

3. The gas injection system of claim 1, wherein each of the plurality of gas outlets is coupled to a respective mass flow sensor only of the plurality of mass flow sensors.

4. The gas injection system of claim 1, wherein each of the plurality of mass flow sensors is coupled to a respective gas valve of the plurality of gas valves.

5. The gas injection system of claim 1, wherein controlling the flow rate through each of the plurality of valves further comprises the controller repeating the steps of receiving a respective flow rate measurement for each of the plurality of gas valves, determining a respective measured flow ratio for each of the plurality of gas valves, determining a respective difference for each of the plurality of valves, and controlling the flow rate for each of the plurality of gas valves.

6. The gas injection system of claim 1, wherein the system is configured such that a total flow of gas through the gas supply line is flowed through the plurality of gas valves.

7. The gas injection system of claim 1, wherein an outlet of each of the plurality of gas valves is fluidly connected to a reaction chamber through a flange.

8. The gas injection system of claim 7, wherein a respective outlet of each of the plurality of gas valves is fluidly connected to a respective flange channel in the flange.

9. The gas injection system of claim 7, wherein the reaction chamber is a horizontal cross flow reactor.

10. The gas injection system of claim 1, further comprising a moisture sample panel.

11. The gas injection system of claim 1, wherein each of the plurality of gas valves and the respective mass flow sensor coupled to the respective gas valve form at least part of a mass flow controller.

12. The gas injection system of claim 1, wherein the plurality of flow sensors comprise pressure drop based flow sensors.

13. The gas injection system of claim 1, wherein the plurality of flow sensors comprise thermal mass flow sensors.

14. A gas injection system, comprising:
a gas source;
a gas supply line fluidly connected to the gas source;
a plurality of gas channels fluidly connected to the gas supply line, wherein the gas supply line is configured to divide a total flow of a gas stream from the gas source into the plurality of gas channels;
a plurality of mass flow controllers, wherein each mass flow controller is disposed on a respective gas channel and configured to measure and control a respective gas flow through the respective gas channel; and
a main controller operatively connected to each of the plurality of mass flow controllers, wherein the main controller is configured to send a respective initial flow ratio setpoint to a respective mass flow controller for each of the plurality of mass flow controllers, and further configured to send a respective feedback flow ratio setpoint to the respective mass flow controller for each of the plurality of mass flow controllers based on a respective determined flow ratio based on measured gas flow through each of the plurality of mass flow controllers.

15. The gas injection system of claim 14, wherein the respective determined flow ratio is the respective measured gas flow through the respective mass flow controller divided by a sum of all measured flow rates through each of the mass flow controllers.

16. The gas injection system of claim 14, wherein a flow rate though each of the plurality of mass flow controllers is controlled using closed-loop control.

17. The gas injection system of claim 14, wherein a flow rate though each of the plurality of mass flow controllers is controlled using open-loop control.

18. The gas injection system of claim 14, wherein a flow rate though each of the plurality of mass flow controllers is controlled using open-loop control and closed-loop control.

19. The gas injection system of claim 14, wherein an outlet of each of the plurality of mass flow controllers is fluidly connected to a reaction chamber through a flange.
